(19) United States
(12) Patent Application Publication
(10) Pub. No.: US 2024/0363362 A1
(43) Pub. Date: Oct. 31, 2024

(54) METHOD FOR FABRICATING SEMICONDUCTOR DEVICE

(71) Applicant: United Semiconductor (Xiamen) Co., Ltd., Xiamen (CN)

(72) Inventors: Wind Zhu, Shamen City (CN); Feng Gao, Shamen City (CN); Wen Yi Tan, Xiamen (CN)

(73) Assignee: United Semiconductor (Xiamen) Co., Ltd., Xiamen (CN)

(21) Appl. No.: 18/201,163

(22) Filed: May 23, 2023

(30) Foreign Application Priority Data
Apr. 26, 2023 (CN) 202310464605.5

(51) Int. Cl. H01L 21/3213; H01L 21/28; H01L 29/40

(52) U.S. Cl. CPC H01L 21/32139; H01L 21/28035; H01L 29/401

(57) ABSTRACT

A method for fabricating a semiconductor device includes steps as follows. A gate material layer is formed on a substrate, wherein the gate material layer includes an amorphous material having a phase transition temperature, and the amorphous material converts into a polycrystalline material at the phase transition temperature. A first hard mask is formed on the gate material layer at a first process temperature, wherein the first process temperature is less than the phase transition temperature. A second hard mask is formed on the first hard mask at a second process temperature, wherein the second process temperature is less than the phase transition temperature.

### BACKGROUND OF THE INVENTION

### 1. Field of the Invention

The present disclosure relates to the field of semiconductor devices, and more particularly, to a method for fabricating a semiconductor device.

### 2. Description of the Prior Art

In the field of semiconductor, poly-silicon gates are gradually replaced by metal gates due to their high resistance and the tendency to generate the depletion effect.

When fabricating a metal gate, a poly-silicon gate may be formed first, and then a replacement metal gate (RMG) process is performed to replace the poly-silicon material in the poly-silicon gate with a metal material to obtain the metal gate. However, the poly-silicon material includes a plurality of grains, which will damage the flatness of the surfaces contacting the poly-silicon material. For example, concave shapes corresponding to the convex contours of the grains will be generated on the spacer surrounding the poly-silicon material or the film layers located below the poly-silicon material. As a result, the performance of the semiconductor device is affected.

Therefore, it is an important issue for the relevant industry to improve the method for fabricating the semiconductor device, such that the semiconductor device fabricated thereby can meet the requirements.

### SUMMARY OF THE INVENTION

According to one aspect of the present disclosure, a method for fabricating a semiconductor device includes steps as follows. A gate material layer is formed on a substrate, wherein the gate material layer includes an amorphous material having a phase transition temperature, and the amorphous material converts into a polycrystalline material at the phase transition temperature. A first hard mask is formed on the gate material layer at a first process temperature, wherein the first process temperature is less than the phase transition temperature. A second hard mask is formed on the first hard mask at a second process temperature, wherein the second process temperature is less than the phase transition temperature.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow diagram showing a method for fabricating a semiconductor device according to one embodiment of the present disclosure.

FIG. 2, FIG. 3, FIG. 4, FIG. 5, FIG. 6 and FIG. 7 are schematic diagrams showing steps of the method for fabricating the semiconductor device shown in FIG. 1.

FIG. 8 and FIG. 9 are schematic diagrams showing steps of a method for fabricating a semiconductor device according to another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

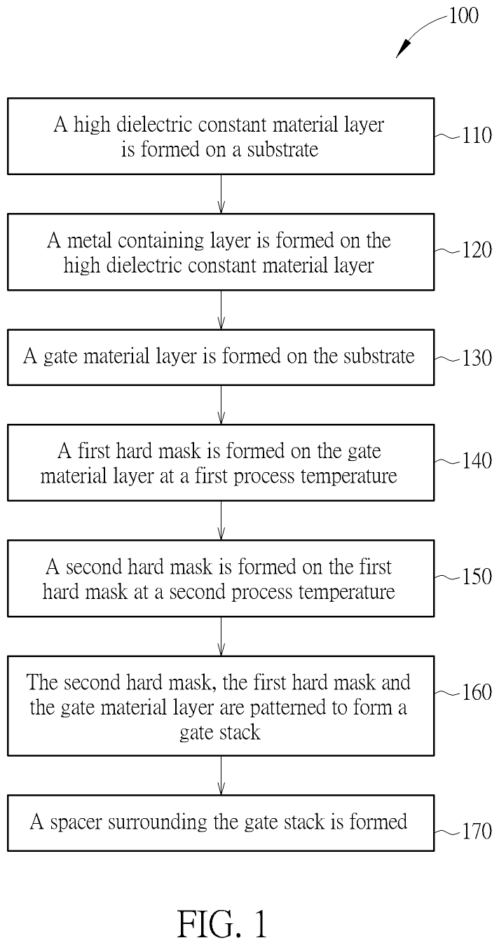

Please refer to FIG. 1, which is a flow diagram showing a method 100 for fabricating a semiconductor device according to one embodiment of the present disclosure. The method 100 for fabricating the semiconductor device includes Step 130 to Step 150. In Step 130, a gate material layer is formed on the substrate, wherein the gate material layer includes an amorphous material having a phase transition temperature, and the amorphous material converts into a polycrystalline material at the phase transition temperature. In Step 140, a first hard mask is formed on the gate material layer at a first process temperature, wherein the first process temperature is less than the phase transition temperature. In Step 150, a second hard mask is formed on the first hard mask at a second process temperature, wherein the second process temperature is less than the phase transition temperature. With the first process temperature and the second process temperature being less than the phase transition temperature, it can prevent the amorphous material from converting into the polycrystalline material in the processes of forming the first hard mask and the second hard mask, which is beneficial to maintain the flatness of the surface contacting the amorphous material, and is beneficial for maintaining the performance of the semiconductor device.

The method 100 for fabricating the semiconductor device may further includes Step 110 and Step 120. In Step 110, a high dielectric constant (high-k) material layer is formed on the substrate. In Step 120, a metal containing layer is formed on the high-k material layer, wherein the gate material layer is disposed on the metal containing layer. That is, the gate material layer is indirectly disposed on the substrate. The method 100 for fabricating the semiconductor device may further includes Step 160 and Step 170. In Step 160, the second hard mask, the first hard mask and the gate material layer are patterned to form a gate stack. In Step 170, a spacer surrounding the gate stack is formed. When the method 100 for fabricating the semiconductor device includes Step 110 and Step 120, the metal containing layer and the high-k material layer are also patterned in Step 160.

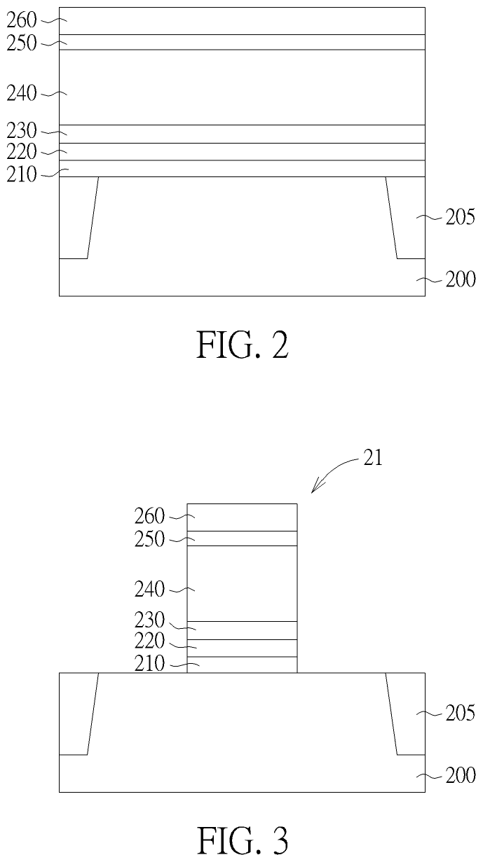

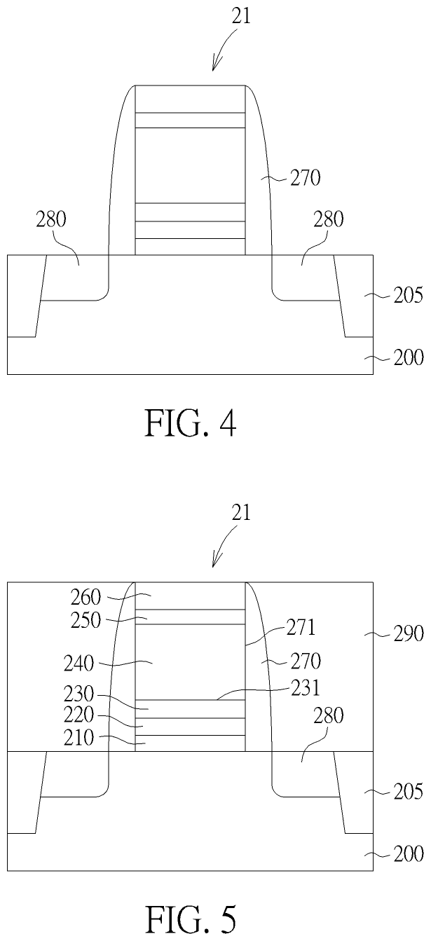

Please refer to FIG. 2 to FIG. 7, which are schematic diagrams showing steps of the method 100 for fabricating the semiconductor device shown in FIG. 1. In FIG. 2, a high-k material layer 220 is firstly formed on the substrate 200 (corresponding to Step 110). The substrate 200 may be a semiconductor substrate such as a silicon substrate, an epitaxial silicon substrate, a silicon carbide substrate or a silicon on insulator (SOI) substrate. The high-k material layer 220 may include a dielectric material with a dielectric constant greater than 4, such as a group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) and a combination thereof. The substrate 200 may be formed with an insulating structure 205 for providing an electrical isolation function in advance. The insulating structure 205 may be, for example, a shallow trench isolation (STI). The material of the insulating structure 205 may include dielectric materials such as silicon dioxide.

Before forming the high-k material layer 220, an interfacial layer 210 may be formed on the substrate 200 to solve the problem of the reduction of the electron mobility of the channel caused by the high-k material layer 220, and then the high-k material layer 220 is formed on the interfacial layer 210. The interfacial layer 210 and the high-k material layer 220 may be used as a gate insulating layer. The material of the interfacial layer 210, for example, may include an oxide, a nitride or nitrogen oxide.

Next, a metal containing layer 230 is selectively form on the high-k material layer 220 (corresponding to Step 120). The metal containing layer 230 may be used as a barrier layer or a work function metal layer. For example, the metal containing layer 230 may include titanium nitride, tantalum nitride or aluminum nitride.

Next, a gate material layer 240 is form on the metal containing layer 230 (corresponding to Step 130). The gate material layer 240 includes an amorphous material, and the amorphous material has a phase transition temperature. The amorphous material can convert into a polycrystalline material at the phase transition temperature. The gate material layer 240 may be formed on the metal containing layer 230 at a process temperature less than the phase transition temperature, so that the amorphous state of the gate material layer 240 can be maintained. The amorphous material, for example, may include amorphous silicon (a-Si), the phase transition temperature may be 590° C. to 610° C., and the process temperature for forming the gate material layer 240 may be less than 590° C., such as 550° C.

A first hard mask 250 is formed on the gate material layer 240 at a first process temperature (corresponding to Step 140), wherein the first process temperature is less than the phase transition temperature. The first hard mask 250 may include a nitride, such as silicon nitride (SiN). In this case, the first process temperature may be greater than or equal to 560° C. and less than 590° C. For example, the first process temperature may be 580° C. The reactants for forming the first hard mask 250 may include hexachlorodisilane (Si₂Cl₆) and ammonia (NH₃).

A second hard mask 260 is formed on the first hard mask 250 at a second process temperature (corresponding to Step 150), wherein the second process temperature is less than the phase transition temperature. The second hard mask 260 may include an oxide, such as silicon dioxide (SiO₂). In this case, the second process temperature may be greater than or equal to 380° C., and less than or equal to 420° C. For example, the second process temperature may be 400° C. The reactants for forming the second hard mask 260 may include silane (SiH₄) and nitrous oxide (N₂O). In the embodiment, the first hard mask 250 includes a nitride, and the second hard mask 260 includes an oxide, both of which are exemplary, and the present disclosure is not limited thereto. The first hard mask 250 and the second hard mask 260 have different etching rates are all within the scope of the present disclosure. For example, the etching selectivity ratio of the first hard mask 250 to the second hard mask 260 may be greater than or equal to 50. The etchant can be selected according to the materials of the first hard mask 250 and the second hard mask 260. When the first hard mask 250 includes the nitride, and the second hard mask 260 includes the oxide, the etchant may include phosphoric acid.

In FIG. 3, the second hard mask 260, the first hard mask 250, the gate material layer 240, the metal containing layer 230, the high-k material layer 220, and the interfacial layer 210 may be patterned through lithography and etching processes to form a gate stack 21 (corresponding to Step 160). The gate stack 21 includes, from bottom to top, a patterned interfacial layer 210, a patterned high-k material layer 220, a patterned metal containing layer 230, a patterned gate material layer 240, a patterned first hard mask 250, and a patterned second hard mask 260. In the present disclosure, it is beneficial to precisely define the pattern of the gate stack 21 by disposing two layers of hard mask (i.e., the first hard mask 250 and the second hard mask 260).

In FIG. 4, a spacer 270 surrounding the gate stack 21 is formed (corresponding to Step 160). The spacer 270 may be a single-layer structure or a multi-layer structure. The material of the spacer 270 may include an oxide and/or a nitride, such as silicon dioxide, silicon nitride, silicon oxynitride, or silicon carbide nitride. Before forming the spacer 270, light doped drains (LDDs) (not shown) may be formed in the substrate 200. The LDDs is located on both sides of the gate stack 21 and below the spacer 270. After the spacer 270 is formed, source/drain regions 280 may be formed in the substrate 200, and the structures of the source/drain regions 280 may be adjusted depending on the finished product being applied to an n-type metal oxide semiconductor (NMOS) transistor or a P-type metal oxide semiconductor (PMOS) transistor. For example, when the finished product is applied to the NMOS transistor, n-type impurities such as arsenic and phosphorus may be implanted in the substrate 200 on both sides of the gate stack 21 to form the source/drain regions 280. For another example, when the finished product is applied to the PMOS transistor, grooves (not shown) may be formed in the substrate 200 on both sides of the gate stack 21 by isotropic or anisotropic etch, and then a selective epitaxial growth (SEG) may be performed to form an epitaxial layer that can provide stress in the grooves. For example, the epitaxial layer may be a silicon germanium epitaxial layer. Next, an ion implantation process may be performed to implant p-type impurities, such as boron and indium, in the epitaxial layer to form the source/drain regions 280.

In FIG. 5, a dielectric layer 290 is formed on the substrate 200. Specifically, a dielectric material may be deposited on the substrate 200 to cover the gate stack 21 and the spacer 270, and then a planarization process such as a chemical mechanical polishing (CMP) process is performed to remove a portion of the dielectric material to expose the second hard mask 260 of the gate stack 21, so that the top surface of the remaining dielectric material is aligned with the top surface of the gate stack 21, and the fabrication of the dielectric layer 290 is completed. The materials of the dielectric layer 290, for example, include silicon may dioxide or tetraethoxysilane (TEOS).

Afterward, a RMG process is performed. As shown in FIG. 6, the second hard mask 260, the first hard mask 250 and the gate material layer 240 are removed to form a groove 295 in the spacer 270. Next, as shown in FIG. 7, a conductive layer 240a is deposited in the groove 295 to obtain the semiconductor device 20. The conductive layer 240a may be a single-layer structure or a multi-layer structure. For example, the conductive layer 240a may be a single-layer structure, which only include a low-resistance metal layer, and the material of the low-resistance metal layer, for example, may be selected from copper (Cu), aluminum (Al), tungsten (W), titanium-aluminum alloy (TiAl), cobalt tungsten phosphide (CoWP) or a combination thereof. For another example, in addition to the low-resistance metal layer, the conductive layer 240a may optionally include a high-k dielectric layer and/or a barrier layer and/or a work function metal layer disposed between the low-resistance metal layer and the metal containing layer 230.

The aforementioned film layers, such as the interfacial layer 210, the high-k material layer 220, the metal containing layer 230, the gate material layer 240, the first hard mask 250 and the second hard mask 260, may be formed by any suitable methods. For example, the methods may be, but are not limited to, molecular-beam epitaxy (MBE), physical vapor deposition (PVD), chemical vapor deposition (CVD), metal organic chemical vapor deposition (MOCVD), sub-atmospheric chemical vapor deposition (SACVD), plasma-enhanced chemical vapor deposition (PECVD), hydride vapor phase epitaxy (HVPE) and atomic layer deposition (ALD).

In the conventional method, the first hard mask 250, for example, may be formed by using dichlorosilane (Si₂H₂Cl₂) and NH₃ as reactants to form a silicon nitride at a first process temperature of 700° C. In the conventional method, the second hard mask 260, for example, may be formed by using TEOS as the reactant to form a silicon dioxide at a second process temperature of 680° C. Compared with the present disclosure, the conventional methods for forming the first hard mask 250 and the second hard mask 260 require higher process temperatures, which will cause the gate material layer 240 to convert from the amorphous material to the polycrystalline material. As a result, concave shapes (not shown) corresponding to the convex contours of the grains may be generated on the surface 271 (see FIG. 5) of the spacer 270 and/or the surface 231 (see FIG. 5) of the metal containing layer 230 contacting the gate material layer 240. That is, when the gate material layer 240 converts from the amorphous material to the polycrystalline material, the flatness of the surface 271 of the spacer 270 and/or the surface 231 of the metal containing layer 230 will be damaged, and the performance of the semiconductor device 20 is affected thereby. In other words, in the present disclosure, it can avoid to damage the surface 271 of the spacer 270 and/or the surface 231 of the metal containing layer 230 with the first process temperature for forming the first hard mask 250 and the second process temperature for forming the second hard mask 260 being less than the phase transition temperature of the gate material layer 240, so as to improve the performance of the semiconductor device 20. According to the testing results, the difference between the saturation current and the leakage current of the semiconductor device 20 according to the present disclosure may be increased by 1.5% to 5% compared with that of a conventional semiconductor device. That is, the semiconductor device 20 fabricated by the method according to the present disclosure can have improved electrical performance.

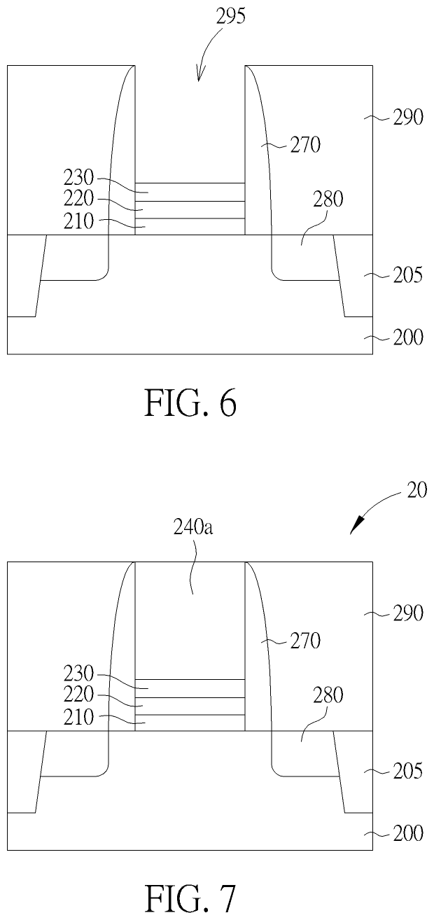

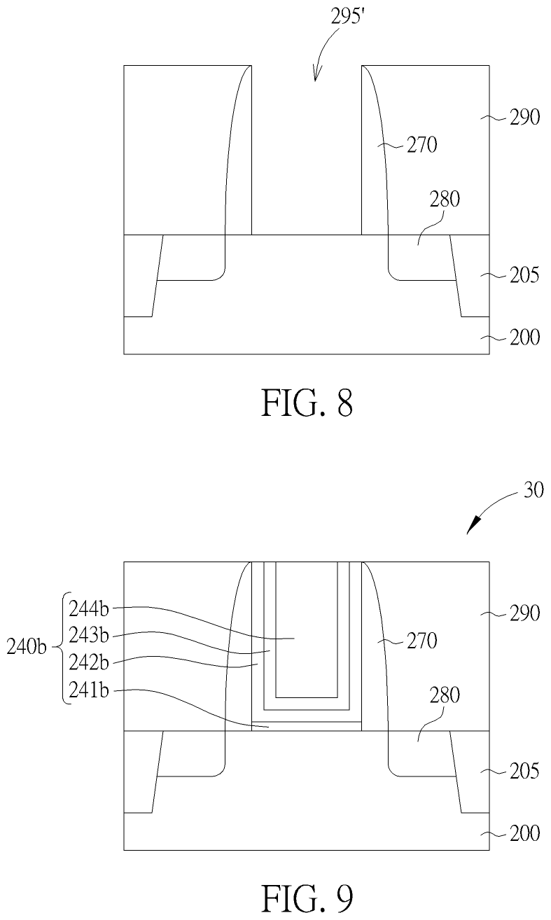

Please refer to FIG. 8 and FIG. 9, which are schematic diagrams showing steps of a method for fabricating a semiconductor device according to another embodiment of the present disclosure. The main difference between the embodiment shown in FIG. 8 to FIG. 9 and the embodiment shown in FIG. 2 to FIG. 7 is the RMG process. In FIG. 8, compared with FIG. 6, not only the second hard mask 260, the first hard mask 250 and the gate material layer 240 are removed, but also the metal containing layer 230, the high-k material layer 220 and the interfacial layer 210 are also removed to form the groove 295′ in the spacer 270. Next, as shown in FIG. 9, the interfacial layer 241b, the high-k material layer 242b, the work function metal layer 243b and the low-resistance metal layer 244b are deposited in the groove 295′ to obtain the metal gate 240b, so as to complete the fabrication of the semiconductor device 30. In addition, depending on actual needs, the metal gate 240b may further include a barrier layer (not shown). For example, the barrier layer may be disposed between the high-k material layer 242b and the work function metal layer 243b or between the work function metal layer 243b and the low-resistance metal layer 244b. For details of the interfacial layer 241b, the high-k material layer 242b and the low-resistance metal layer 244b, references may be made to the above description related the interfacial layer 210, the high-k material layer 220 and the low-resistance metal layer in FIG. 7 and are not repeated herein. In the embodiment, it can prevent the surface 271 (See FIG. 5) of the spacer 270 from being damaged with the first process temperature for forming the first hard mask 250 and the second process temperature for forming the second hard mask 260 being less than the phase transition temperature of the gate material layer 240.

Compared with the prior art, in the present disclosure, with the first process temperature and the second process temperature being less than the phase transition temperature, it can prevent the amorphous material from converting into the polycrystalline material in the processes of forming the first hard mask and the second hard mask, which is beneficial to maintain the flatness of the surface contacting the amorphous material, so as to improve the performance of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a gate material layer on a substrate, wherein the gate material layer comprises an amorphous material having a phase transition temperature, and the amorphous material converts into a polycrystalline material at the phase transition temperature;
forming a first hard mask on the gate material layer at a first process temperature, wherein the first process temperature is less than the phase transition temperature; and
forming a second hard mask on the first hard mask at a second process temperature, wherein the second process temperature is less than the phase transition temperature.

2. The method of claim 1, wherein the amorphous material comprises amorphous silicon, and the phase transition temperature is 590° C. to 610° C.

3. The method of claim 1, wherein the first hard mask comprises a nitride.

4. The method of claim 3, wherein the first process temperature is greater than or equal to 560° C., and is less than 590° C.

5. The method of claim 3, wherein reactants for forming the first hard mask comprises hexachlorodisilane and ammonia.

6. The method of claim 1, wherein the second hard mask comprises an oxide.

7. The method of claim 6, wherein the second process temperature is greater than or equal to 380° C., and is less than or equal to 420° C.

8. The method of claim 6, wherein reactants for forming the second hard mask comprise silane and nitrous oxide.

9. The method of claim 1, further comprising:
forming a high dielectric constant material layer on the substrate; and
forming a metal containing layer on the high dielectric constant material layer, wherein the gate material layer is disposed on the metal containing layer.

10. The method of claim 1, further comprising:
patterning the second hard mask, the first hard mask and the gate material layer to form a gate stack; and
forming a spacer surrounding the gate stack.
